(19) United States
(12) Patent Application Publication
(10) Pub. No.: US 2025/0102371 A1
(43) Pub. Date: Mar. 27, 2025

(54) MEMS METAMATERIAL AND MEMS DEVICE INCORPORATING THE MEMS METAMATERIAL

(71) Applicant: STMicroelectronics International N.V., Geneva (CH)

(72) Inventors: Luca GUERINONI, Alzano Lombardo (IT); Gianfranco Javier YALLICO SANCHEZ, Rozzano (IT); Davide BERNABUCCI, Ravenna (IT); Carlo VALZASINA, Gessate (IT); Claudia COMI, Milano (IT); David FARACI, Colverde (IT)

(73) Assignee: STMicroelectronics International N.V., Geneva (CH)

(21) Appl. No.: 18/895,219

(22) Filed: Sep. 24, 2024

(30) Foreign Application Priority Data
Sep. 27, 2023 (IT) 102023000019974

(51) Int. Cl. G01K 7/34

(52) U.S. Cl. CPC G01K 7/34

(57) ABSTRACT

A MEMS metamaterial has a substrate and a suspended structure having an elementary cell which extends at a distance from the substrate along a first direction. The elementary cell has a first structural region having a first material with a first coefficient of thermal expansion. The first structural region has a first side facing the substrate and a second side opposite to the first side. The elementary cell also has a second structural region having a second material different from the first material and with a second coefficient of thermal expansion different from the first coefficient of thermal expansion. The second structural region extends on at least part of the first structural region, on the first side, the second side, or both the first and second side of the first structural region.

### BACKGROUND

### Technical Field

The present disclosure relates to a MEMS (Micro Electro-Mechanical Systems) metamaterial and to a device incorporating the MEMS metamaterial.

### Description of the Related Art

As known, a metamaterial is an artificial material whose structure and composition are configured to obtain specific physical properties (for example electromagnetic, acoustic or mechanical). For example, a metamaterial may have physical properties that are not normally found in nature or in the individual materials that form the metamaterial.

For example, electromagnetic metamaterials are known whose structure and composition are configured to obtain negative refractive indices.

Metamaterials are also known to have specific mechanical properties as the temperature varies, for example metamaterials having a coefficient of thermal expansion that may be modulated in the design step, depending on the specific application. However, the Applicant has observed that these known metamaterials cannot be easily integrated into MEMS devices, i.e., obtainable through micro/nano manufacturing techniques.

### BRIEF SUMMARY

According to the present disclosure, a MEMS metamaterial and a device incorporating the MEMS metamaterial are provided.

According to the present disclosure, a MEMS metamaterial is provided. The MEMS metamaterial comprises a substrate, fixed electrodes coupled to the substrate, and a suspended structure configured to move in relation to two or more of the fixed electrodes. The suspended structure further including an elementary cell positioned at a distance from the substrate along a first direction. The elementary cell includes a first structural region, including a first material, containing silicon, with a first coefficient of thermal expansion. The first structural region has a first side facing the substrate and a second side opposite to the first side. The elementary cell additionally includes a second structural region, including a second material, different from the first material, having a second coefficient of thermal expansion different from the first coefficient of thermal expansion. The second structural region is positioned on a part of the first structural region, being on at least one among the first side of the first structural region and the second side of the first structural region.

According to the present disclosure, a device including a MEMS metamaterial is provided. The device comprises a substrate and a suspended structure, including an elementary cell positioned at a distance from the substrate along a first direction. The elementary cell includes a first structural region containing silicon, and the first structural region further includes a plurality of border portions positioned transversely to each other. The elementary cell has a second structural region containing metal positioned on the first structural region. Finally, the elementary cell includes a constraint structure positioned between and coupled to two or more border portions of the first structural region.

### BRIEF DESCRIPTION OF THE SEVERAL VIEWS OF THE DRAWINGS

For a better understanding of the present disclosure, embodiments are now described, purely by way of non-limiting example, with reference to the attached drawings, wherein:

FIG. 1 shows a top-plan view of a MEMS metamaterial, according to one embodiment;

FIG. 2 shows an enlarged portion of the MEMS metamaterial of FIG. 1;

FIG. 3 shows a perspective view of an elementary cell of the MEMS metamaterial of FIG. 1;

FIG. 4 shows a top-plan view of the cell of FIG. 3;

FIG. 5 shows a cross-section of a portion of the metamaterial of FIG. 1;

FIG. 6 shows an example of a simulation of the deformation due to thermal variation of an elementary cell of the MEMS metamaterial of FIG. 1, according to an embodiment;

FIG. 7 shows a simulation of the deformation due to thermal variation of a MEMS metamaterial, according to one embodiment;

FIG. 8 shows a simulation of the deformation due to thermal variation of a MEMS metamaterial, according to a different embodiment;

FIGS. 9 and 10 show the trend of expansion and curvature due to thermal variations of the MEMS metamaterial of FIG. 1, as geometric parameters vary;

FIG. 11 shows an embodiment of a MEMS device incorporating a MEMS metamaterial;

FIG. 12 shows a cross-section of the MEMS device of FIG. 11, at rest, along a section line XII-XII;

FIG. 13 shows the cross-section of FIG. 12, in use;

FIG. 14 shows a different embodiment of a MEMS device incorporating a MEMS metamaterial;

FIG. 15 shows a cross-section of the MEMS device of FIG. 14, at rest, along a section line XV-XV;

FIG. 16 shows the cross-section of FIG. 15, in use; and

FIG. 17 shows an elementary cell of a MEMS metamaterial, according to a different embodiment.

### DETAILED DESCRIPTION

The following description refers to the arrangement shown in the attached Figures; consequently, expressions such as “above,” “below,” “lower,” “upper,” “right,” “left,” “top,” “bottom,” and the like, relate to the attached Figures and should not be interpreted in a limiting manner.

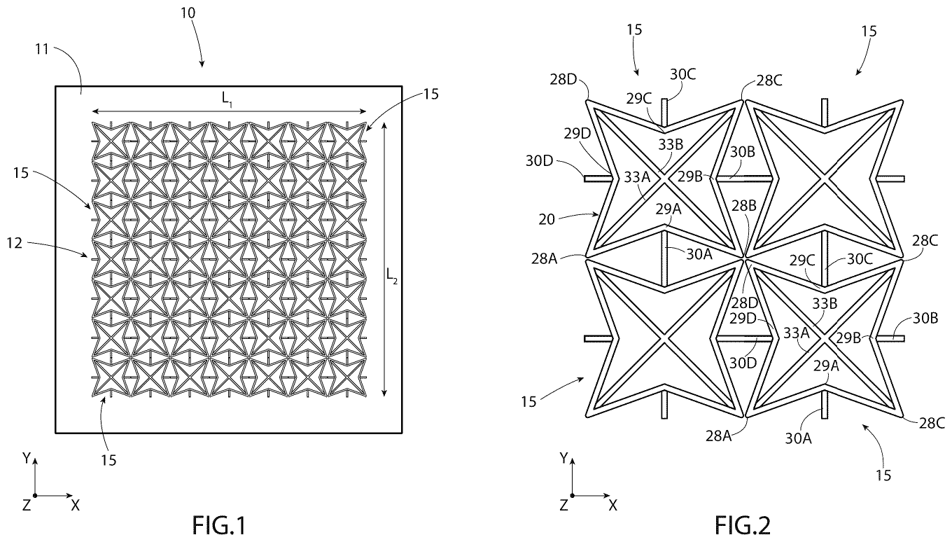

FIGS. 1 and 2 show a MEMS metamaterial 10 in a Cartesian reference system XYZ comprising a first axis X, a second axis Y and a third axis Z.

The MEMS metamaterial 10 is a structure that may be formed through per se known micro/nano manufacturing techniques typical of the semiconductor industry for the manufacturing of MEMS devices.

The MEMS metamaterial 10 may be incorporated into a MEMS device.

The MEMS metamaterial 10 comprises a substrate 11 and a suspended structure 12 suspended on the substrate 11. For example, the substrate 11 may be a body of semiconductor, insulating or metal material, depending on the specific application, for example silicon, glass, sapphire or other materials typically used for manufacturing MEMS devices.

One or more support regions, not shown here, may extend between the suspended structure 12 and the substrate 11, so as to mechanically support the suspended structure 12 over the substrate 11. Number and arrangement of the support regions may be chosen, in the design step, depending on the specific application of the MEMS metamaterial 10.

The suspended structure 12 of the MEMS metamaterial 10 comprises a plurality of elementary cells 15 mechanically coupled to each other, in particular integral with each other. In the embodiment of FIG. 1, the elementary cells 15 are mutually coupled so as to form a two-dimensional lattice, in particular here of size 7×7, having a main extension parallel to a XY plane.

The suspended structure 12 has, at rest, a length L₁, measured along the first axis X, and a length L₂ measured along the second axis Y. The lengths L₁, L₂ depend on the number of elementary cells 15 and the size of each of the elementary cells 15. For example, the lengths L₁, L₂ is comprised between a few tens of micrometers and a few millimeters, depending on the specific design needs.

In the following it is considered, for simplicity and purely by way of example, that all the elementary cells 15 are equal to each other. However, the elementary cells 15 may differ from each other, for example due to manufacturing variability or depending on the specific application and design needs.

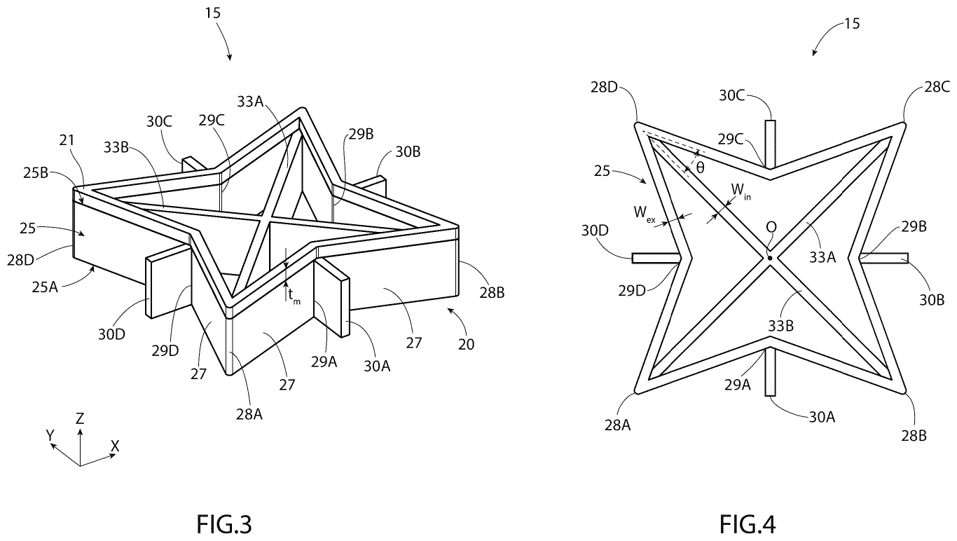

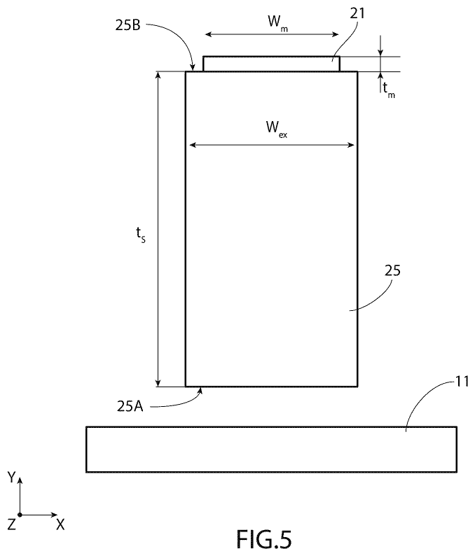

FIGS. 3 and 4 show in detail a generic elementary cell, for simplicity still indicated by the number 15, of the MEMS metamaterial 10.

The elementary cell 15 comprises a lower structural region, here formed by a semiconductor layer 20, for example of silicon, in particular of polycrystalline silicon; and an upper structural region, here formed by a metal layer 21, for example of nickel, aluminum, chromium, copper alloys, etc., extending on at least part of the semiconductor layer 20.

In practice, the semiconductor layer 20 and the metal layer 21 form a partial and non-symmetric stratification along the third axis Z of the elementary cell 15.

The semiconductor layer 20 and the metal layer 21 are formed by two materials having coefficients of thermal expansion different from each other.

In particular, the metal layer 21 is formed of a material having a coefficient of thermal expansion greater than the material that forms the semiconductor layer 20.

The semiconductor layer 20 has a thickness tₛ, along the third axis Z, comprised for example between 5 μm and 60 μm.

The metal layer 21 has a thickness tₘ, along the third axis Z, comprised for example between 0.5 μm and 5 μm.

The semiconductor layer 20 is patterned, through per se known micro/nano manufacturing techniques, so as to form a perimeter wall 25.

The perimeter wall 25 has a width Wₑₓ, measured in the XY plane, comprised for example between 1 μm and 10 μm.

The perimeter wall 25 has a lower surface 25A arranged on a first side of the semiconductor layer 20 that faces the substrate 11, and an upper surface 25B arranged on a second side of the semiconductor layer 20 that is opposite to the first side along the third axis Z.

The perimeter wall 25 is continuous, that is it may form a closed border, or is discontinuous, that is it may have one or more discontinuities and thus form an open border.

In this embodiment, the perimeter wall 25 forms a closed border; in particular, it forms the external border of a non-convex spatial region of star-domain or star-set shape with angles smaller than 90° (tips) and angles greater than 90° (recesses).

The perimeter wall 25 is formed by a plurality of border portions 27 arranged transversally to each other in space and joined to each other, in particular here joined to each other at the respective ends.

In detail, the border portions 27 are mutually joined so as to form one or more protruding portions (or tips) of the perimeter wall 25, in particular here four tips 28A-28D, and one or more recessing portions (or recesses) of the perimeter wall 25, in particular here four recesses 29A-29D, which alternate one with the other.

Any one or more of the number of tips and recesses, the length of each border portion 27 (i.e., the distance between a tip, for example tip 28A, of the perimeter wall 25 and an adjacent recess, for example recess 29A, of the perimeter wall 25), the opening angle of each tip 28A-28D, and the angle of each recess 29A-29D (i.e., the angle formed between two border portions 27 adjacent to each other) may be chosen as a function of the specific design needs and the specific application.

In this embodiment, the border portions 27 are arranged in such a way that the perimeter wall 25 has, in top-plan view in the XY plane, a symmetrical structure with respect to a center O of the elementary cell 15. In particular, all the border portions 27 have the same length and all the tips 28A-28D and all the recesses 29A-29D have the same opening angle; this allows the same deformation behavior of the MEMS metamaterial 10 to be obtained along the first and the second axes X, Y.

The semiconductor layer 20 is also patterned so as to form, for each elementary cell 15, one or more coupling portions, here four coupling portions 30A-30D.

The coupling portions 30A-30D each extend from the perimeter wall 25 towards the outside of the respective elementary cell 15.

The coupling portions 30A-30D work as mechanical coupling elements for coupling the elementary cell 15 to an adjacent elementary cell 15.

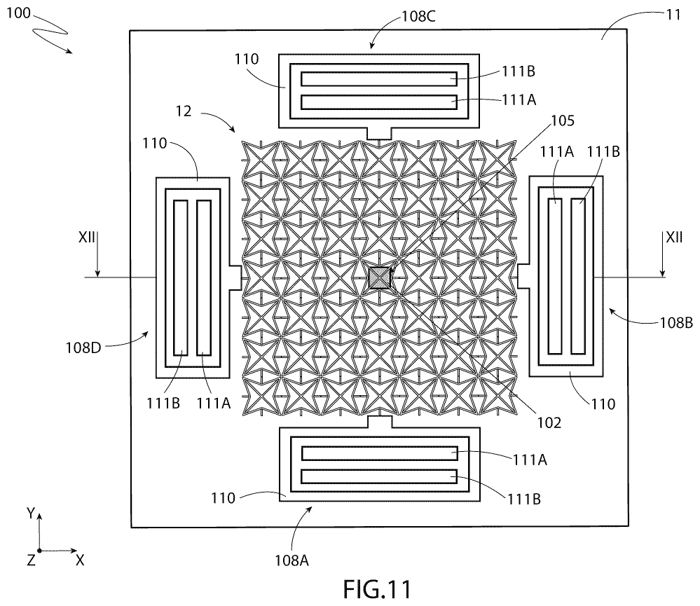

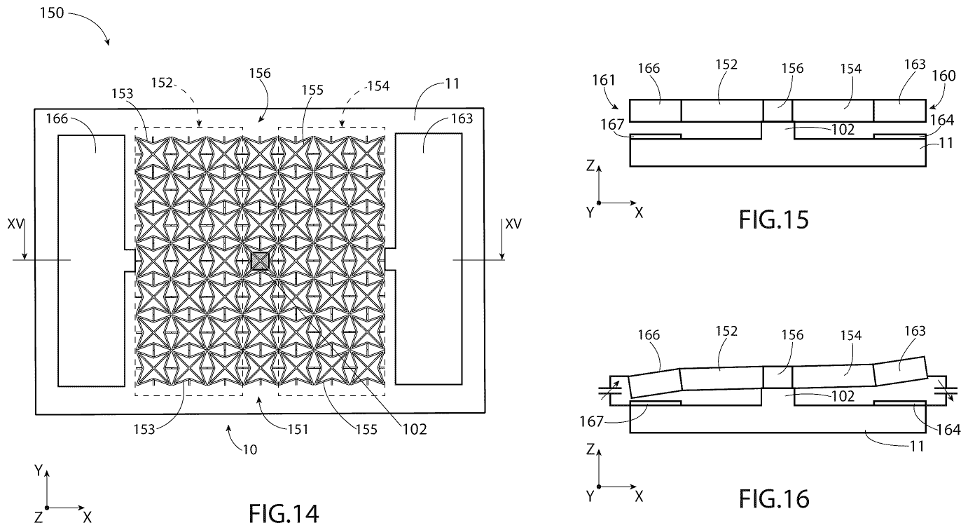

Furthermore, the coupling portions 30A-30D, in particular the coupling portions of the peripheral elementary cells 15 (i.e., of the elementary cells 15 which form the external perimeter of the two-dimensional lattice of the MEMS metamaterial 10) is used for the mechanical coupling of the MEMS metamaterial 10 to specific functional elements of the MEMS device wherein the MEMS metamaterial 10 is incorporated, such as for example discussed below with reference to FIGS. 11 and 14.

In particular, in the embodiment shown, the coupling portions 30A-30D each extend starting from a respective recess 29A-29D of the perimeter wall 25. This allows for maximizing (or minimizing) the absolute value of the maximum deformation obtainable from the MEMS metamaterial in response to a temperature variation. For example, when the MEMS metamaterial is configured to have a negative coefficient of thermal expansion, this allows the maximum negative deformation of the MEMS metamaterial to be optimized, in response to an increase in temperature.

The coupling portions 30A-30D have a length, measured along the first and the second axes X, Y as per arrangement of FIGS. 1-4, such as to allow the coupling of the respective elementary cell 15 with the adjacent elementary cells 15 while avoiding contact between the tips 28A-28D of the respective elementary cell 15 with the tips 28A-28D of the adjacent elementary cells 15.

The semiconductor layer 20 is also patterned so as to form, for each elementary cell 15, one or more connection arms, here two connection arms 33A, 33B which mechanically couple the tips 28A-28D of the respective elementary cell 15 to each other.

The connection arms 33A, 33B have a width Wᵢₙ, measured in the XY plane transverse to the third axis Z, in particular here the same width as each other, for example comprised between 1 μm and 10 μm.

The connection arms 33A, 33B extend inside the perimeter wall 25.

The connection arm 33A extends from the tip 28A to the tip 28C, in particular through the center O.

The connection arm 33B extends from the tip 28B to the tip 28D, in particular through the center O.

In practice, the connection arm 33A is a constraint element between the tip 28A and the tip 28C and the connection arm 33B is a constraint element between the tip 28B and the tip 28D. The connection arms 33A, 33B form a constraint structure.

The connection arms 33A, 33B each form a respective angle θ with the border portion 27 of the respective tip 28A-28D, as indicated schematically in FIG. 4 for the connection arm 33B and the tip 28D.

Furthermore, in this embodiment, the connection arms 33A, 33B are also coupled to each other, in particular they are joined to each other at the center O. This allows the mechanical stiffness of the elementary cell 15 to be increased, and, in response to a temperature variation, the selected deformation, curvature, or both deformation and curvature of the elementary cell 15 to be favored.

The connection arms 33A, 33B may have a shape and structure different from what has been shown, for example they may extend with a non-straight shape.

The metal layer 21 extends on the upper surface 20A of the perimeter wall 25. In particular, in this embodiment, the metal layer 21 extends, along a direction that follows the perimeter wall 25 on the XY plane, throughout the length of the perimeter wall 25; this may favor obtaining the selected deformation behavior of the elementary cell 15.

The metal layer 21 has a width Wₘ which may be smaller than (FIG. 5) or equal to the width Wₑₓ of the perimeter wall 25, for example according to specific manufacturing needs.

The Applicant has verified that by using two structural regions arranged one on top of the other and comprising materials with coefficients of thermal expansion different from each other, it is possible to design an elementary cell of a MEMS metamaterial having a specific deformation type and extent, as the temperature varies.

In particular, the Applicant has observed that by varying the materials of the semiconductor layer 20 and the metal layer 21 and by varying the geometric parameters (for example one or more of the dimensions tₘ, tₛ, Wₑₓ, Wᵢₙ, Wₘ) of the elementary cells 15 vary, it is possible to modify the deformation type and extent undergone by the individual elementary cells 15 (and therefore the entire suspended structure 12 of the MEMS metamaterial 10 as a whole) as the temperature varies.

In particular, the elementary cells 15 are configured to be subject, in response to a temperature variation, to an in-plane deformation (i.e., an expansion or contraction along the first, the second, or both the first and second axes X, Y), an out-of-plane deformation (i.e., an upward or downward curvature, along the third axis Z), or both an in-plane and out-of-plane deformation having the selected sign and modulus, depending on the specific application of the MEMS metamaterial 10.

Therefore, overall, the suspended structure 12 is configurable, in the design step, so as to be subject, in response to a temperature variation, to a deformation that depends on the semiconductor layer 20 and on the metal layer 21, in particular on the respective materials and geometric parameters.

For example, by modifying materials and geometric parameters of the elementary cells 15 the elementary cells 15 and therefore, overall, also the suspended structure 12 is caused to have a tunable equivalent coefficient of thermal expansion.

With reference to the elementary cell 15, the equivalent coefficient of thermal expansion indicates the variation of a dimension of the elementary cell 15 in response to a temperature variation, for example the variation of a dimension measured along the first or the second axis X, Y such as for example the distance along the first axis X between two opposite coupling portions 30B, 30D.

With reference to the suspended structure 12, the equivalent coefficient of thermal expansion indicates the variation of a dimension of the suspended structure 12 in response to a temperature variation, for example the variation of one of, or both, the lengths L₁, L₂.

It is therefore clear that the MEMS metamaterial 10 has a high versatility and may be incorporated into MEMS devices usable in a wide range of applications.

Furthermore, the fact that the elementary cells 15 of the MEMS metamaterial 10 are formed by the semiconductor layer 20 and the metal layer 21 arranged one on top of the other allows a simple integration of the manufacturing of the MEMS metamaterial 10 within a typical manufacturing process of a MEMS device. The MEMS metamaterial 10 may therefore be easily incorporated into MEMS devices.

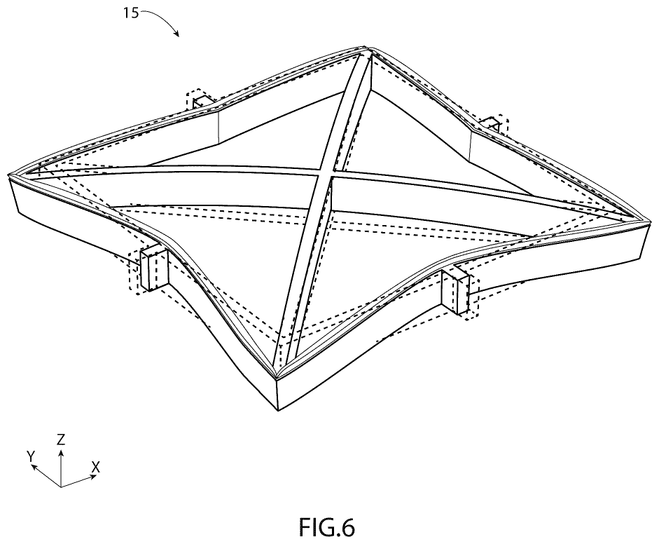

FIG. 6 shows, purely by way of example, the result of a simulation of the deformation of a generic elementary cell 15, in response to a positive temperature variation (temperature increase). In detail, FIG. 6 shows, in a dashed line and without color filling, the elementary cell 15 at rest (undeformed) and, in a solid line with color filling, the elementary cell 15 deformed in response to the temperature increase. In the example shown, the semiconductor layer 20 has a positive coefficient of thermal expansion and the metal layer 21 has a coefficient of thermal expansion that is positive and greater than that of the semiconductor layer 20. Furthermore, the geometric parameters of the elementary cell 15 have been modulated so that the elementary cell 15 has, overall, a negative equivalent coefficient of thermal expansion.

In fact, as visible in FIG. 6, the recesses 29A-29D are each subject to a displacement in the XY plane towards the inside of the elementary cell 15 (moving closer to the center O along the first or the second axis X, Y). Consequently, the coupling portions 30A-30D also move closer to the center O with respect to the rest position. In practice, overall, the elementary cell 15 is subject to a contraction in the XY plane in response to a temperature increase.

The presence of the plurality of elementary cells 15 coupled to each other through the respective coupling portions 30A-30D causes the MEMS metamaterial 10 to also be subject, as a whole, to a reduction, with respect to the rest state, of the lengths L₁, L₂ of the suspended structure 12, in response to a temperature increase. The greater the number of elementary cells 15, the greater the overall contraction of the suspended structure 12 of the MEMS metamaterial 10.

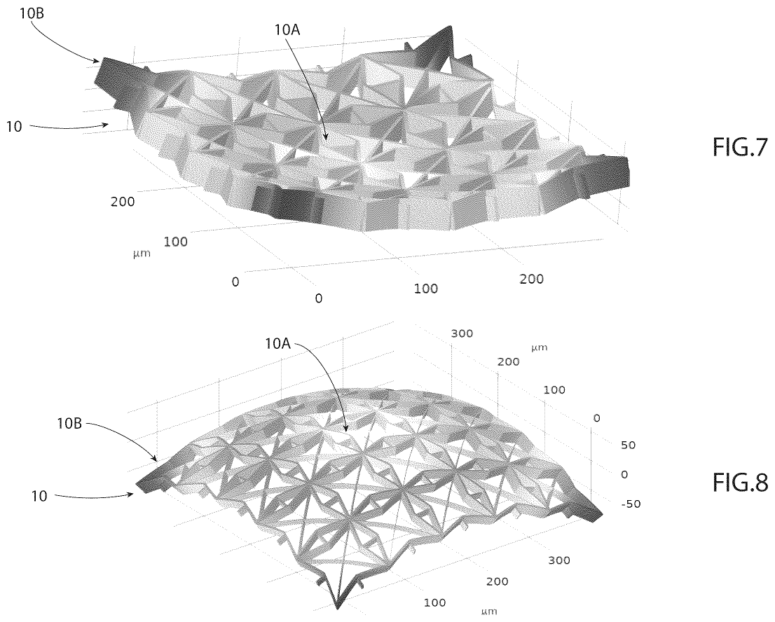

Purely by way of example, FIG. 7 shows a simulation of the deformation of the suspended structure 12 of the MEMS metamaterial 10, in a case in which θ=25°, tₛ=20 μm, Wᵢₙ=3 μm and tₘ=4 μm. The simulation shows that, as the temperature increases, the suspended structure 12 of the MEMS metamaterial 10 is subject to positive curvature. In practice, with reference to the arrangement of FIG. 7, the central portion 10A of the suspended structure 12 is subject to a downward displacement along the third axis Z, while the peripheral portion 10B is subject to an upward displacement along the third axis Z.

Purely by way of example, FIG. 8 shows a simulation of the deformation of the suspended structure 12, in a case in which θ=30°, tₛ=10 μm, Wᵢₙ=5 μm and tₘ=1 μₘ. The simulation shows that, as the temperature increases, the suspended structure 12 is subject to a negative curvature, i.e., opposite to that of the example of FIG. 7. In practice, with reference to the arrangement of FIG. 8, the central portion 10A of the suspended structure 12 is subject to an upward displacement, while the peripheral portion 10B of the suspended structure 12 is subject to a downward displacement.

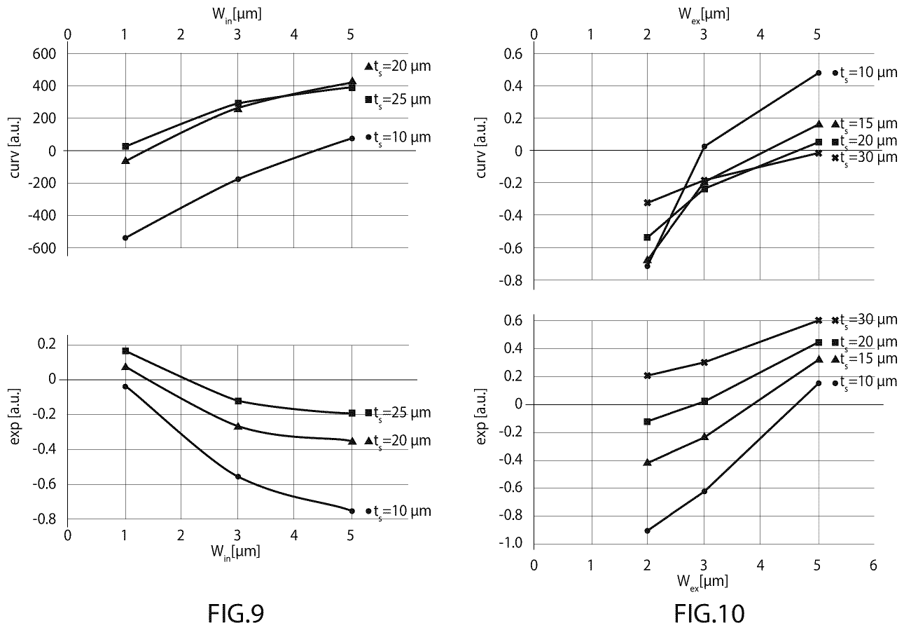

FIG. 9 is a further example wherein the trend of the curvature, ‘curv’, and the expansion, ‘exp’, of the suspended structure 12 (in response to a temperature variation) is shown on a plot wherein θ=30° and tₘ=5 μₘ, as a function of the width Wᵢₙ of the connection arms 33A, 33B of the elementary cells 15, for different values of the thickness tₛ of the semiconductor layer 20. As may be noted, by modulating the width Wᵢₙ and the thickness tₛ, the curvature and the expansion to which the suspended structure 12 is subject may be modified as the temperature varies.

In particular, it may be noted that the suspended structure 12, for example for tₛ=20 μₘ and Wᵢₙ ˜ 1.3 μₘ in the example shown, may have both zero curvature and zero expansion in response to a temperature variation. In other words, the MEMS metamaterial 10 may be configured so that the suspended structure 12 is not subject to any deformation, at least as a first approximation, as the temperature varies.

FIG. 10 is a further example wherein the trend of the curvature, ‘curv’, and the expansion, ‘exp’, of the MEMS metamaterial 10 (in response to a temperature increase) is shown on a plot wherein θ=30° and Wᵢₙ=2.3 μₘ, as a function of the width Wₑₓ of the perimeter wall 25 of the elementary cells 15, for different values of the thickness tₛ of the semiconductor layer 20. As may be noted, by modulating the width Wₑₓ and the thickness tₛ, it is possible to modify the curvature and the expansion to which the suspended structure 12 is subject as the temperature varies.

In particular, it may be noted that the suspended structure 12, for example for tₛ=10 μₘ and Wₑₓ ˜3 μₘ in the example shown, may have zero curvature and negative expansion in response to an increase in temperature. In other words, the MEMS metamaterial 10 may be configured so that the suspended structure 12 is subject to, at least as a first approximation, an in-plane deformation and is not subject to any out-of-plane deformation as the temperature varies.

In practice, each elementary cell 15 and, consequently, also the suspended structure 12, is configured to have an equivalent coefficient of thermal expansion different from that of the semiconductor layer 20 and the metal layer 21; for example, the equivalent coefficient of thermal expansion may be positive, negative, or zero. In particular, the equivalent coefficient of thermal expansion may be greater than the greatest of the coefficient of thermal expansion of the semiconductor layer 20 and the metal layer 21 or smaller than the smallest of the coefficient of thermal expansion of the semiconductor layer 20 and the metal layer 21.

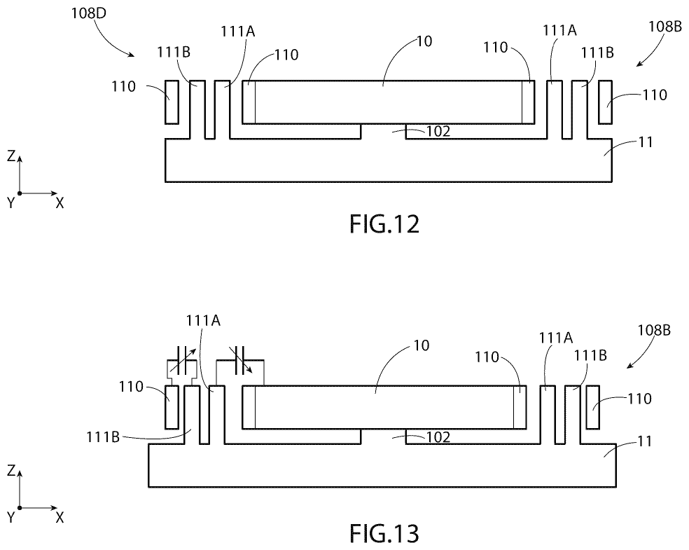

FIGS. 11 and 12 show, in the Cartesian reference system XYZ, a MEMS temperature sensor 100, hereinafter referred to as MEMS sensor 100, incorporating the MEMS metamaterial 10.

The suspended structure 12 of the MEMS metamaterial 10 is configured to be subject to a non-zero deformation in response to a temperature variation and to have a coefficient of thermal expansion different from that of the substrate 11.

In practice, the suspended structure 12 of the MEMS metamaterial 10 is the element of the MEMS sensor 100 which is sensitive to temperature variations.

A support region 102 extends, along the third axis Z, between the suspended structure 12 and the substrate 11. In practice, the support region 102 maintains, at rest, the suspended structure 12 suspended on the substrate 11.

The support region 102 may be of the same material, for example silicon, of which the substrate 11 is formed.

In this embodiment, the support region 102 is integral with the substrate 11 and with a central elementary cell 105 of the MEMS metamaterial 10. In practice, the support region 102 is coupled, in particular fixed, to the center of the two-dimensional lattice formed by the MEMS metamaterial 10. This confers a high mechanical stability, both at rest and in use, to the MEMS metamaterial 10 and therefore a high operating reliability to the MEMS sensor 100.

The MEMS sensor 100 further comprises one or more sensing structures, here four sensing structures 108A-108D, configured to sense a deformation of the MEMS metamaterial 10 as the temperature varies.

The sensing structures 108A-108D are capacitive sensing structures.

In detail, the sensing structures 108A-108D each comprise at least one movable electrode 110, suspended on the substrate 11 and coupled to the MEMS metamaterial 10, and at least one fixed electrode, here two fixed electrodes 111A, 111B, integral with the substrate 11 and arranged at a distance from the respective movable electrode 110.

In this embodiment, the movable electrode 110 of each sensing structure 108A-108D is coupled to a respective peripheral elementary cell of the plurality of elementary cells 15. In particular, the movable electrodes 110 are each integral with one of the connection portions 30A-30D of the respective elementary cell 15.

For example, the movable electrodes 110 are formed through patterning of the semiconductor layer 20.

Furthermore, in this embodiment, the movable electrodes 110 each have a through cavity which extends throughout the thickness, along the third axis Z, of the movable electrode 110.

The fixed electrodes 111A, 111B extend from the substrate 11 within the cavity of the respective movable electrode 110.

The MEMS sensor 100 also comprises reading circuits, not shown here and known per se, for reading the capacitance between the movable electrode 110 and the respective fixed electrodes 111A, 111B.

In use, a temperature variation causes a deformation of the suspended structure 12 and the substrate 11. Since the suspended structure 12 has a different coefficient of thermal expansion than that of the substrate 11, the increase in temperature causes a variation of the distance between the movable electrode 110 and the respective fixed electrodes 111A, 111B and, therefore, of the respective capacitances.

With reference to the example of FIG. 13, in response to a temperature increase, the movable electrode 110 moves closer to the respective fixed electrode 111B (resulting in a capacitance increase) and moves away from the respective fixed electrode 111A (resulting in a capacitance decrease). In practice, the presence of two fixed electrodes 111A, 111B allows a differential sensing of the temperature.

By reading the capacitance variations, it is possible to obtain a measurement of the temperature variation to which the MEMS sensor 100 has been subject, for example through specific conversion tables obtainable during the calibration step of the MEMS sensor 100.

In particular, in this embodiment, in response to a temperature increase, the suspended structure 12 is configured to contract (negative coefficient of thermal expansion) while the substrate 11 expands (positive coefficient of thermal expansion). This allows the variation in the distance between movable electrodes 110 and fixed electrodes 111A, 111B to be maximized, and therefore the sensitivity of the MEMS sensor 100 to be improved.

According to one embodiment, the suspended structure 12 is configured to be subject, in response to an increase in temperature, to a non-zero in-plane expansion or contraction and, as a first approximation, a zero out-of-plane expansion (curvature). This allows avoiding errors in reading the capacitances by the sensing structures 108A-108D, and therefore a greater accuracy of the MEMS sensor 100.

According to one embodiment, the suspended structure 12 is configured to have a coefficient of thermal expansion having opposite sign (for example a negative sign) with respect to the coefficient of thermal expansion of the substrate 11 (for example a positive sign).

FIGS. 14 and 15 show a MEMS temperature sensor 150. The sensor incorporates the MEMS metamaterial 10 having a suspended structure 151 arranged on the substrate 11.

The suspended structure 151 comprises a first portion 152 (on the left in FIG. 14) having a plurality of elementary cells 153, and a second portion 154 (on the right in FIG. 14) having a plurality of elementary cells 155.

The elementary cells 153, 155 have a general structure equal to that described with reference to FIGS. 1-5 and, as a result, are not further described in detail. In particular, the elementary cells 153, 155 are arranged so as to form each a respective two-dimensional lattice having, in top-plan view, five rows and three columns.

The elementary cells 153 are configured to have a first curvature and the elementary cells 155 are configured to have a second curvature that is opposite to the first curvature, in response to a same temperature variation.

The suspended structure 151 also has a central portion 156, arranged between the first and the second portions 152, 154 parallel to the first axis X.

The MEMS sensor 150 also comprises the support region 102, which here extends between the substrate 11 and the central portion 156 of the MEMS metamaterial 151.

The MEMS sensor 150 comprises two capacitive sensing structures 160, 161 configured to sense a displacement of the suspended structure 151, with respect to the substrate 11, along the third axis Z.

The sensing structure 160 comprises a movable electrode 163 suspended on the substrate 11 and integral with the second portion 154 of the suspended structure 151, and a fixed electrode 164 integral with the substrate 11. The fixed electrode 164 and the movable electrode 163 face, at rest, each other along the third axis Z.

The sensing structure 161 comprises a movable electrode 166 suspended on the substrate 11 and integral with the first portion 152 of the suspended structure 151, and a fixed electrode 167 integral with the substrate 11. The fixed electrode 167 and the movable electrode 166 face each other, at rest, along the third axis Z.

In use, in presence of a temperature variation, the first and the second portions 152, 154 of the suspended structure 151 deform along two directions parallel to the third axis Z and opposite to each other. For example, with reference to the example shown in FIG. 16, the first portion 152 of the suspended structure 151 is subject to a downward curvature (coming close to the substrate 11), while the second portion 154 of the suspended structure 151 is subject to an upward curvature (moving away from the substrate 11).

Consequently, the sensing structures 160, 161 are subject to two capacitance variations, with respect to the rest value, having opposite sign. This allows a differential measurement of the temperature variation to be obtained.

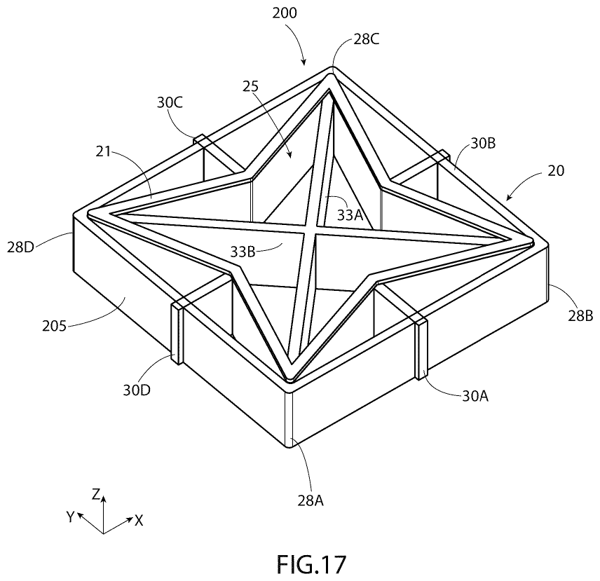

FIG. 17 shows a different embodiment of an elementary cell, here indicated by 200, which may be used to form a MEMS metamaterial similarly to what has been described with reference to FIGS. 1-5. The elementary cell 200 has a general structure similar to that of the elementary cells 15 described with reference to FIGS. 1-5; consequently, common elements are indicated by the same reference number and are not further described in detail.

The elementary cell 200 comprises the semiconductor layer 20, patterned so as to form the perimeter wall 25, the connection arms 33A, 33B and the coupling portions 30A-30D, and the metal layer 21.

Furthermore, in this embodiment, the semiconductor layer 20 is patterned so as to also form a further perimeter wall 205 which extends around the elementary cell 200. The further perimeter wall 205 mechanically couples the tips 28A-28D of the perimeter wall 25 with each other, in particular it is integral with the perimeter wall 25.

In particular, in top-plan view, the further perimeter wall 205 has a square shape.

In practice, in this embodiment, the further perimeter wall 205 is a constraint structure of the tips 28A-28D arranged externally to the perimeter wall 25.

Furthermore, in this embodiment, the further perimeter wall 205 is also mechanically coupled to, in particular integral with, the coupling portions 30A-30D.

In use, the elementary cell 200 has a behavior similar to that described with reference to the elementary cell 15 and may therefore be configured to have, in response to a temperature variation, a negative, positive or zero equivalent coefficient of thermal expansion, and a positive, negative or zero thermal curvature.

Finally, it is clear that modifications and variations may be made to the MEMS metamaterial and the MEMS device which incorporates the MEMS metamaterial described and illustrated herein without thereby departing from the scope of the present disclosure.

The elementary cells 15, 200 may have a different shape from what has been shown and described.

For example, the elementary cells 15, 200 may have, in top-plan view, a different symmetry from that shown or have no symmetry at all.

For example, the elementary cells 15, 200 may have a different number of tips, recesses or both tips and recesses, depending on the specific implementation.

For example, the perimeter wall 25 may internally delimit a spatial region that does not form a star domain.

For example, the border portions 27 of the perimeter wall 25 may have different dimensions from each other.

For example, the widths Wᵢₙ and Wₑₓ may be uniform or non-uniform along the thickness tₛ of the semiconductor layer 20, for example due to manufacturing variability or specific design needs.

For example, the perimeter wall 25, the connection arms 33A, 33B, the connection portions 30A-30D, and the wall 205 may have thicknesses different from each other along the third axis Z.

The metal layer 21 may not be continuous on the perimeter wall 25, i.e. it may be formed by multiple portions distinct from each other.

For example, the arrangement of the metal layer 21 may be different among the elementary cells.

For example, the metal layer 21 may extend not on the upper surface 25A, but on the lower surface 25B. Or, it may extend both on the upper surface 25A and on the lower surface 25B.

In addition, the metal layer 21 may also extend on other parts of the semiconductor layer 20.

For example, the lower structural region of each elementary cell may also comprise layers or portions of material different from the semiconductor layer 20, and the upper structural region may also comprise layers or portions of material different from the metal layer 21, for example depending on the specific manufacturing needs.

For example, any one or more of the lower structural region comprising the perimeter wall 25, the connection arms 33A, 33B, the coupling portions 30A-30D, and the wall 205, may not be of semiconductor material and the upper structural region may not be of metal material, as long as they comprise materials having a coefficient of thermal expansion different from each other.

For example, a further layer, for example of insulating material, may be arranged along the third axis Z between the semiconductor layer 20 and the metal layer 21, completely or partially. In practice, the semiconductor layer 20 and the metal layer 21 may not be in contact with each other, depending on the specific design or manufacturing needs.

For example, the MEMS metamaterial may be incorporated into MEMS devices different from a temperature sensor, wherein it is beneficial to have a controlled deformation as a function of temperature variations, for example sensors of different type or actuators.

For example, the sensing structures of the sensors 100, 150 may be based on a different sensing mechanism, such as piezoelectric, piezoresistive, etc.

Finally, the different embodiments described above may be combined to provide further solutions.

The present MEMS metamaterial (10) is be summarized as comprising a substrate (11) and a suspended structure (12; 151) which comprises at least one elementary cell (15; 153, 155; 200) extending at a distance from the substrate along a first direction (third axis Z). The elementary cell comprises: a first structural region (20) comprising a first material having a first coefficient of thermal expansion, the first structural region having a first side (25A) facing the substrate (11) and a second side (25B) opposite to the first side; and a second structural region (21) comprising a second material different from the first material and having a second coefficient of thermal expansion different from the first coefficient of thermal expansion, the second structural region (21) extending on at least part of the first structural region (20), on the first side, the second side, or both the first side and second side of the first structural region. In particular, the suspended structure is configured to be subject, in response to a temperature variation, to a deformation which depends on the first structural region and on the second structural region.

In practice, materials and geometric parameters of the first and the second structural regions may be adjusted, in the design step, in such a way as to modify the deformation to which the suspended structure is subject in response to the temperature variation, thus obtaining the selected deformation type and extent, depending on the specific application of the MEMS metamaterial. In other words, the deformation of the suspended structure in response to the temperature variation is tunable in the design step.

In addition, the first structural region includes a perimeter wall (25) having a width (Wₑₓ), measured in a plane (for example the XY plane) transverse to the first direction (third axis Z), which is comprised between 1 μₘ and 10 μₘ.

In addition, the first structural region also includes a constraint structure (33A, 33B) which extends between two protruding portions (28A-28D) of the perimeter wall and has a width (Wᵢₙ), measured in the plane (XY) transverse to the first direction, comprised between 1 μₘ and 10 μₘ.

The first structural region (20) has, along the first direction (Z), a thickness (tₛ) comprised between 5 μₘ and 60 μₘ.

The second structural region (21) has, along the first direction (Z), a thickness (tₘ) comprised between 0.5 μₘ and 5 μₘ.

A MEMS metamaterial (10) comprising: a substrate (11); and a suspended structure (12; 151) comprising at least one elementary cell (15; 153, 155; 200) extending at a distance from the substrate along a first direction (Z), wherein the at least one elementary cell comprises: a first structural region (20) comprising a first material having a first coefficient of thermal expansion, the first structural region having a first side (25A) facing the substrate (11) and a second side (25B) opposite to the first side; and a second structural region (21) comprising a second material different from the first material and having a second coefficient of thermal expansion different from the first coefficient of thermal expansion, the second structural region (21) extending on at least part of the first structural region (20), on the first side, the second side, or both the first and second side of the first structural region.

The first structural region (20) includes a perimeter wall (25) having one or more protruding portions (28A-28D) which extend towards the outside of the elementary cell and one or more recessing portions (29A-29D) which extend towards the inside of the elementary cell, coupled to each other.

The perimeter wall (25) includes at least two protruding portions (28A-28D) and a recessing portion (29A-29D) arranged between the two protruding portions, the first structural region further comprising a constraint structure (33A, 33B; 33A, 33B, 205) which extends between the two protruding portions.

The perimeter wall (25) includes a plurality of border portions (27) extending transversely to each other in space so as to form a closed lateral perimeter of the elementary cell (15; 153, 155; 200).

The constraint structure (33A, 33B; 33A, 33B, 205) extends internally, externally, or both internally and externally to the perimeter wall.

The second structural region (21) extends on at least part of the perimeter wall (25).

The first structural region further include at least one coupling portion (30A-30D) which extends from the perimeter wall (25) towards the outside of the elementary cell.

The at least one coupling portion (30A-30D) is coupled to the recessing portion of the perimeter wall.

The at least one elementary cell is a first elementary cell of a plurality of mutually coupled elementary cells, each elementary cell comprising a respective first structural region (20) and a respective second structural region (21).

The second structural region (21) extends on the second side (25B) of the first structural region (20).

The first material is a semiconductor material, the second material is a metal material, or both the first material is a semiconductor material and the second material is a metal material.

The second coefficient of thermal expansion is greater than the first coefficient of thermal expansion.

The first and the second structural regions are configured so that the suspended structure (12) has an equivalent coefficient of thermal expansion, for example referred to a dimension (L₁, L₂) of the suspended structure along a second direction (X, Y) transverse to the first direction (Z), which is different from the first and the second coefficients of thermal expansion, for example higher than the greatest of the first and the second coefficients of thermal expansion or lower than the smallest of the first and the second coefficients of thermal expansion.

The first and the second structural regions are configured so that the suspended structure (12) has a negative equivalent coefficient of thermal expansion, for example referred to a dimension (L₁, L₂) of the suspended structure along a second direction (X, Y) transverse to the first direction (Z).

The suspended structure is configured to be subject, in response to the temperature variation, to a curvature with respect to a plane (XY) transverse to the first direction (Z), the curvature depending on the first and the second structural regions.

A MEMS device (100; 150; 250) including the MEMS metamaterial.

The MEMS device is a temperature sensor, the suspended structure (12; 151) being configured to be subject to a non-zero deformation in response to the temperature variation, for example to have a negative equivalent coefficient of thermal expansion, the MEMS device further comprising a sensing structure (108A-108D; 160, 161) configured to sense a deformation of the suspended structure (12; 151) with respect to the substrate, in response to a temperature variation.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A MEMS metamaterial comprising:
a substrate;
at least two fixed electrodes coupled to the substrate; and
a suspended structure configured to move in relation to the at least two fixed electrodes, the suspended structure including an elementary cell at a distance from the substrate along a first direction,
wherein the elementary cell includes:
a first structural region including a first material having a first coefficient of thermal expansion, the first structural region having a first side facing the substrate and a second side opposite to the first side; and
a second structural region including a second material different from the first material and having a second coefficient of thermal expansion different from the first coefficient of thermal expansion, and the second structural region on the second side of the first structural region.

2. The MEMS metamaterial according to claim 1, wherein the first structural region includes a perimeter wall having one or more protruding portions which are positioned towards the outside of the elementary cell and one or more recessing portions which are positioned towards the inside of the elementary cell, and are coupled to each other.

3. The MEMS metamaterial according to claim 2, wherein the perimeter wall includes at least two protruding portions and a recessing portion between the two protruding portions, the first structural region further including a constraint structure which is between the two protruding portions.

4. The MEMS metamaterial according to claim 2, wherein the perimeter wall includes a closed lateral perimeter of the elementary cell from a plurality of border portions positioned transversely to each other in space.

5. The MEMS metamaterial according to claim 4, wherein the constraint structure is positioned internally, externally, or both internally and externally to the perimeter wall.

6. The MEMS metamaterial according to claim 2, wherein the second structural region is positioned on at least a part of the perimeter wall.

7. The MEMS metamaterial according to claim 2, wherein the first structural region further includes a coupling portion which is positioned to face towards the outside of the elementary cell.

8. The MEMS metamaterial according claim 7, wherein the coupling portion is coupled to the recessing portion of the perimeter wall.

9. The MEMS metamaterial according to claim 1, wherein the elementary cell is a first elementary cell of a plurality of mutually coupled elementary cells, and the first elementary cell includes a respective first structural region and a respective second structural region.

10. The MEMS metamaterial according to claim 1, wherein the second structural region is positioned on the second side of the first structural region.

11. The MEMS metamaterial according to claim 1, wherein the first material is a semiconductor material, the second material is a metal material, or both the first material is a semiconductor material and the second material is a metal material.

12. The MEMS metamaterial according to claim 1, wherein the second coefficient of thermal expansion is greater than the first coefficient of thermal expansion.

13. The MEMS metamaterial according to claim 1, wherein, in response to the first coefficient of thermal expansion of the first structural region and the second coefficient of thermal expansion of the second structural region, the suspended structure has an equivalent coefficient of thermal expansion, which is different from the first and the second coefficients of thermal expansion.

14. The MEMS metamaterial according to claim 1, wherein, in response to the first coefficient of thermal expansion of the first structural region and the second coefficient of thermal expansion of the second structural region, the suspended structure has a negative equivalent coefficient of thermal expansion.

15. The MEMS metamaterial according to claim 1, wherein the suspended structure is configured to be subject, in response to a temperature variation, to a curvature with respect to a plane transverse to the first direction, the curvature depending on the first and the second structural regions.

16. A device, comprising:
a substrate; and
a suspended structure including an elementary cell positioned at a distance from the substrate along a first direction,
wherein the elementary cell further includes:
a first structural region including a first material containing silicon and having a first side facing the substrate and a second side opposite to the first side; and
a second structural region including a second material containing metal positioned on the second side of the first structural region.

17. The device according to claim 16, wherein the elementary cell is part of a plurality of elementary cells included in the suspended structure, the suspended structure configured to move in relation to two or more fixed electrodes coupled to the substrate, and
wherein the suspended structure is configured to be subject to a curvature with respect to a plane transverse to the first direction.

18. A device, comprising:
a substrate; and
a suspended structure including an elementary cell positioned at a distance from the substrate along a first direction,
wherein the elementary cell further includes:
a first structural region containing silicon, the first structural region further including a plurality of border portions positioned transversely to each other,
a second structural region containing metal on the first structural region; and
a constraint structure positioned between and coupled to two or more border portions of the first structural region.

19. The device according to claim 18, wherein the elementary cell is part of a plurality of elementary cells included in the suspended structure, the suspended structure coupled to two or more movable electrodes, and moving in relation to fixed electrodes coupled to the substrate.

20. The device according to claim 19, comprising a temperature sensor including the suspended structure being configured to be subject to a non-zero deformation in response to a temperature variation, and a sensing structure configured to sense a deformation of the two or more movable electrodes coupled to the suspended structure with respect to the fixed electrodes coupled to the substrate, in response to the temperature variation.
